(19) United States
(12) Patent Application Publication
(10) Pub. No.: US 2012/0139021 A1
(43) Pub. Date: Jun. 7, 2012

(54) SEMICONDUCTOR DEVICE AND METHOD OF FABRICATING THE SAME

(75) Inventors: Seok-Hyun Kim, Seoul (KR); Deok-Sung Hwang, Suwon-si (KR); Yun-Jae Lee, Seoul (KR); Chul Lee, Seoul (KR); Yoon-Taek Jang, Seongnam-si (KR); Chang-Hoon Jeon, Goyang-si (KR); Sang-Bin Ahn, Goyang-si (KR); Jun-Hyeok Ahn, Hwaseong-si (KR)

(73) Assignee: SAMSUNG ELECTRONICS CO., LTD., Suwon-si (KR)

(21) Appl. No.: 13/241,435

(22) Filed: Sep. 23, 2011

(30) Foreign Application Priority Data
Dec. 2, 2010 (KR) 10-2010-0122274

(51) Int. Cl. H01L 27/108

(52) U.S. Cl. 257/296; 257/E27.084

(57) ABSTRACT

A semiconductor memory device includes a transistor having a channel region buried in a substrate and source/drain regions formed to provide low contact resistance. A field isolation structure is formed in the substrate to define active structures. The field isolation structure includes a gap-fill pattern, a first material layer surrounding the gap-fill pattern, and a second material layer surrounding at least a portion of the first material layer. Each active structure includes a first active pattern having a top surface located beneath the level of the top surface of the field isolation structure, and a second active pattern disposed on the first active pattern and whose top is located above the level of the top surface of the field isolation structure.

### PRIORITY STATEMENT

This U.S. non-provisional patent application claims priority under 35 U.S.C. §119 to Korean Patent Application No. 10-2010-0122274, filed on Dec. 2, 2010, in the Korean Intellectual Property Office, the entire contents of which are hereby incorporated by reference.

### BACKGROUND

The inventive concept generally relates to semiconductor devices and methods of fabricating the same. More particularly, the inventive concept relates to semiconductor devices having a buried channel array transistor and to methods of fabricating the same.

As the integration density of semiconductor devices becomes greater, the electrical resistance of conductive elements of the semiconductor devices becomes greater. For instance, as the active region of a substrate of a semiconductor device becomes smaller, the contact resistance between a source/drain region and a contact plug disposed on the source/drain region has increased. Such an increased contact resistance detracts from the reliability of the semiconductor device.

### SUMMARY

According to an aspect of the inventive concept, there is provided a semiconductor device, comprising: a field isolation structure disposed in a substrate, and an active structure surrounded by the field isolation structure, wherein the field isolation structure includes a gap-fill pattern, a first material layer surrounding the gap-fill pattern, and a second material layer interposed between the first material layer and the gap-fill pattern with the first material layer surrounding at least a portion of the second material layer, the active structure includes a first active pattern having a top surface located beneath the level of the top surface of the field isolation structure, and a second active pattern protruding upwardly from the first active pattern to such an extent that the top thereof is located above the level of the top surface of the field isolation structure, the first active pattern comprises a buried channel region of a transistor, and the second active pattern contacts the second material layer.

According to another aspect of the inventive concept, there is provided a method of fabricating a semiconductor device, comprising: forming a trench in a substrate, sequentially forming a first material layer and a second material layer in the trench, subsequently forming an insulating pattern to fill what remains of the trench, etching an upper portion of the first active pattern to form a first hollow exposing a portion of the first material layer, etching the first material layer exposed by the first hollow to form a second hollow wider than the first hollow, and forming a second active pattern that fills the second hollow.

According to yet another aspect of the inventive concept, there is provided a method fabricating a semiconductor device, comprising: forming a trench in a substrate that delimits an active region of the substrate elongated in a first direction when viewed in plan, filling the trench with insulating material to form a field isolation structure, subsequently etching the active region to form a first hollow, doping the active region, widening the first hollow in a second direction that crosses the first direction when viewed in plan to form a second hollow, filling the second hollow with a pattern of active material, and forming at least one contact plug electrically connected to the active material that fills the second hollow.

### BRIEF DESCRIPTION OF THE DRAWINGS

These and other aspects of the inventive concept will be more clearly understood from the following detailed description of the preferred embodiments thereof made with reference to the accompanying drawings. In the drawings:

FIG. 1A is a plan view of a semiconductor device according to the inventive concept;

FIG. 1B is an enlarged view of a portion P of the device in FIG. 1A;

FIGS. 2A, 3A, . . . 15A are sectional views taken in a cell array region along line I-I′ of FIG. 1 during the course of a method of fabricating the semiconductor device according to the inventive concept;

FIGS. 2B, 3B, . . . 15B are sectional views taken in the cell array region along line II-II′ of FIG. 1 during the course of the method of fabricating the semiconductor device according to the inventive concept;

FIGS. 2C, 3C, . . . 15C are sectional views taken in a peripheral region along line III-III′ of FIG. 1 during the course of the method of fabricating the semiconductor device according to the inventive concept;

FIG. 16A is a block diagram of a memory card including a memory device according to the inventive concepts; and

FIG. 16B is a block diagram of an information processing system including a memory device according to the inventive concept.

### DETAILED DESCRIPTION OF THE PREFERRED EMBODIMENTS

Various embodiments and examples of embodiments of the inventive concept will be described more fully hereinafter with reference to the accompanying drawings. The drawings are not necessarily to scale. That is, in the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, like numerals are used to designate like elements throughout the drawings.

It will also be understood that when an element or layer is referred to as being “on” or “connected to” another element or layer, it can be directly on or directly connected to the other element or layer or intervening elements or layers may be present. In contrast, when an element or layer is referred to as being “directly on” or “directly connected to” another element or layer, there are no intervening elements or layers present.

Furthermore, spatially relative terms, such as “top,” and “bottom” are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use. In addition, the term “top” or “bottom” as used to describe a surface, for example, generally refers not only to the orientation depicted in the drawings but to the fact that the feature is the uppermost or bottommost surface/point in the orientation depicted, as would be clear from the drawings and context of the written description.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. The term “pattern” may refer to a layer or individual feature(s) formed as the result of some patterning (etching) process. The term “extend” usually indicates the longitudinal, i.e., lengthwise, direction of a particular element or a direction in which a feature is elongated in a particular plane. Thus, the term “wider” will generally pertain to a dimension in a direction perpendicular to the lengthwise or elongated direction.

A semiconductor device and a method of fabricating a semiconductor device according to the inventive concept will now be described in detail with reference to the accompanying drawings.

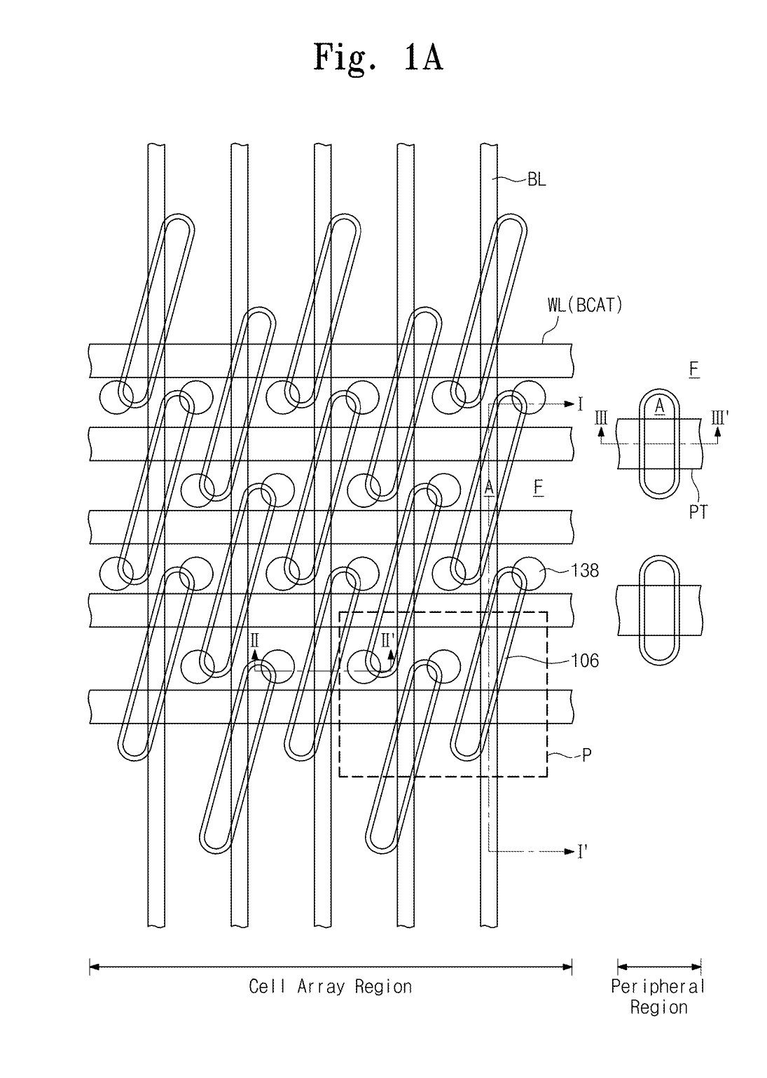

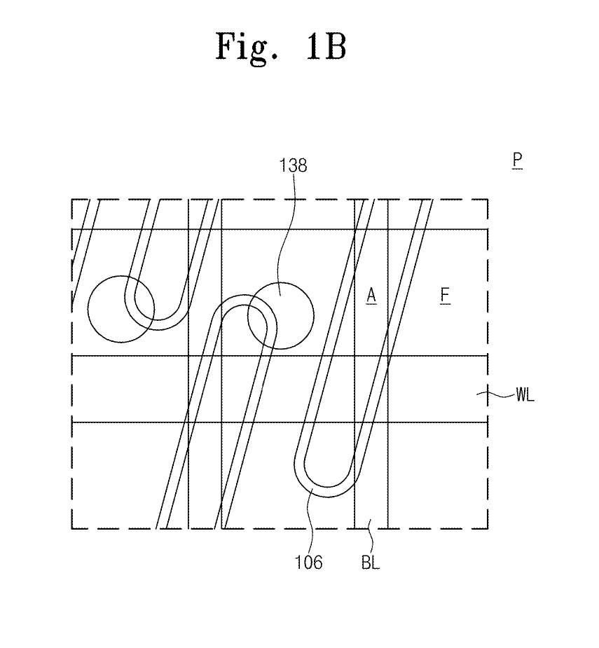

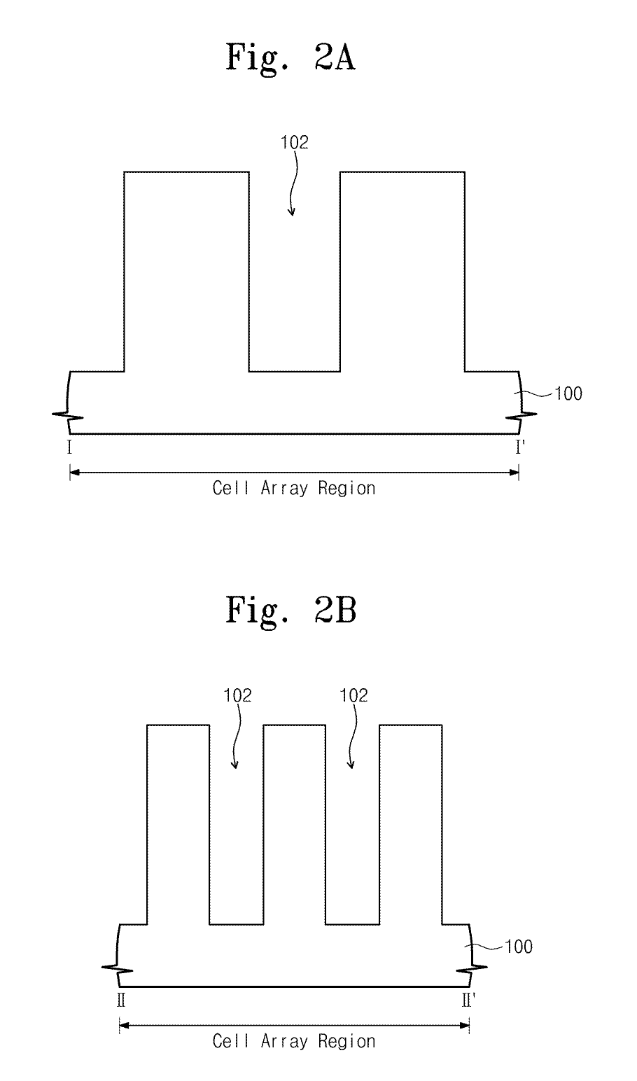

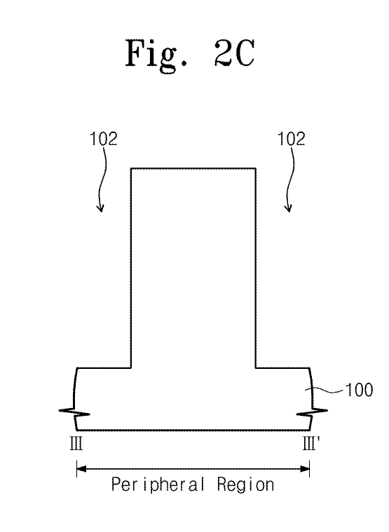

Referring to FIGS. 1A, 1B, and 2A through 2C, a substrate 100 is provided. The substrate 100 may be a semiconductor substrate formed of silicon or germanium or a silicon-on-insulator (SOI) substrate. Moreover, the substrate 100 has a cell array region and a peripheral region.

Trenches 102 are formed in a substrate 100. More specifically, a first mask (not shown) is formed on the substrate 100, and the substrate 100 is etched using the first mask as an etch mask. In this respect, the substrate 100 may be etched using an anisotropic etching technique such as a plasma etching technique or a reactive ion etching technique. As a result, however, surfaces of the substrate 100 formed by the forming of the trenches 102 may have damage. Note, the forming of the trenches 102, as well as the processes that follow, are performed at both the cell array region and the peripheral region of the substrate 100, unless as clearly indicated otherwise.

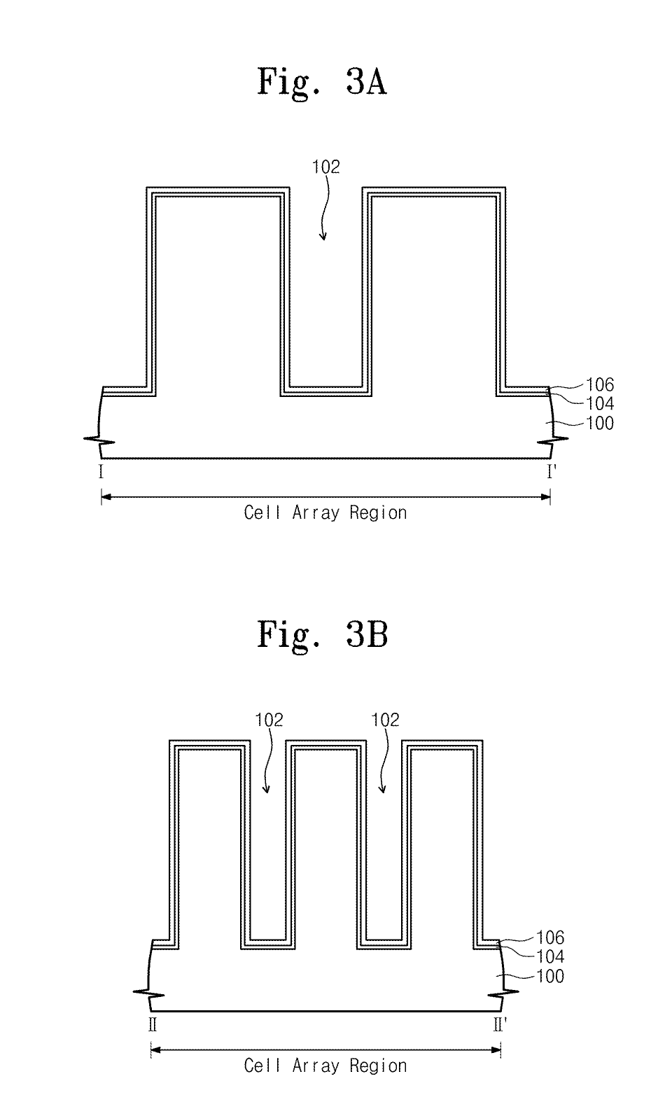

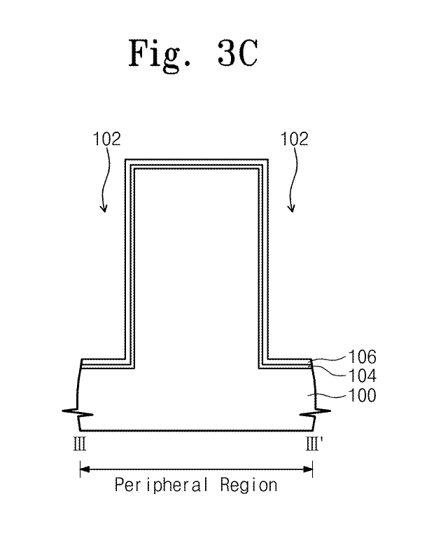

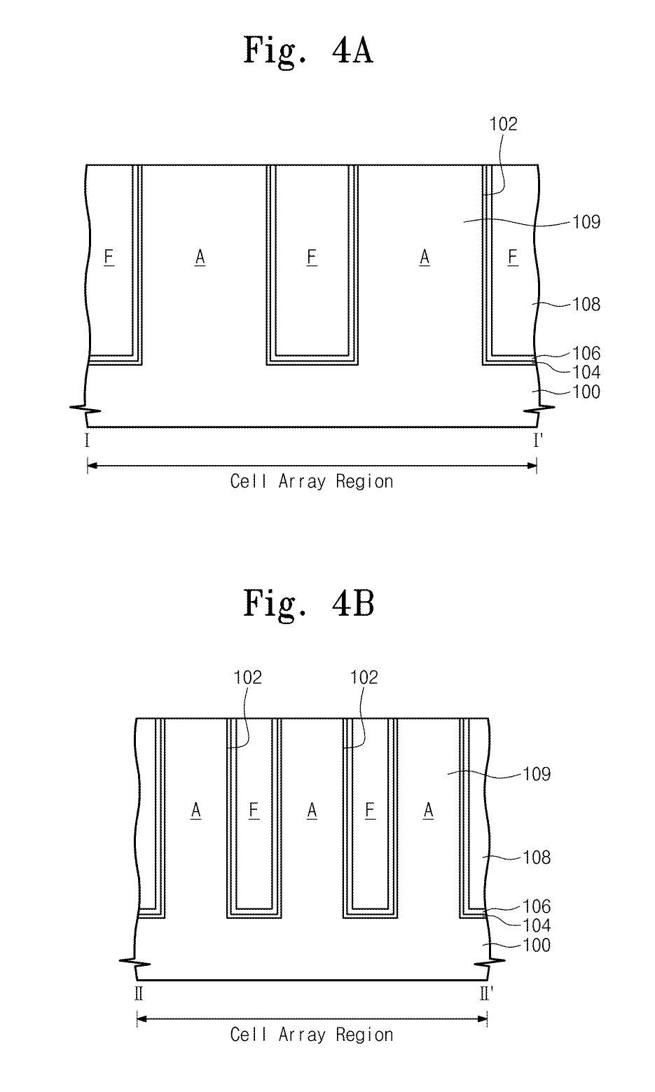

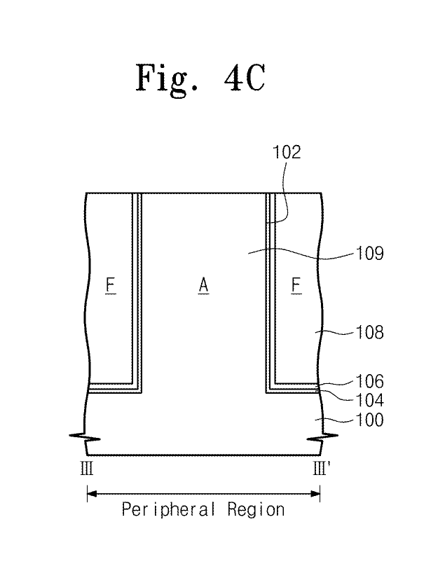

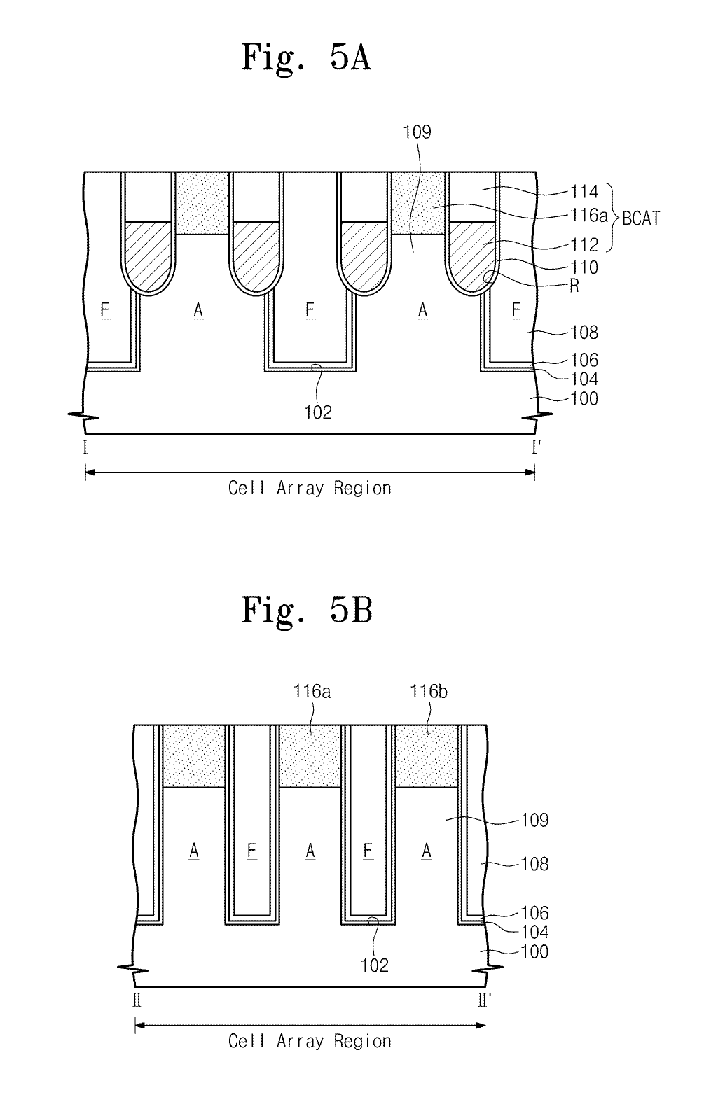

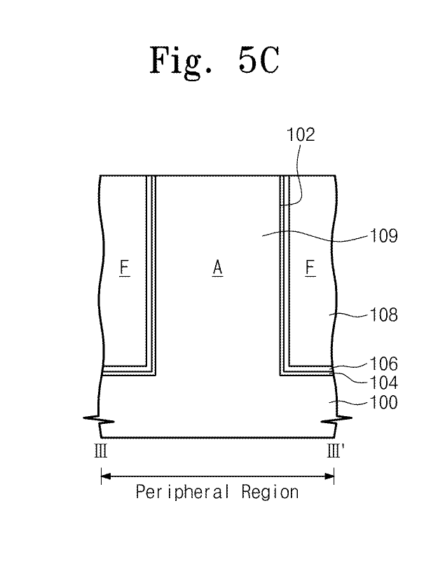

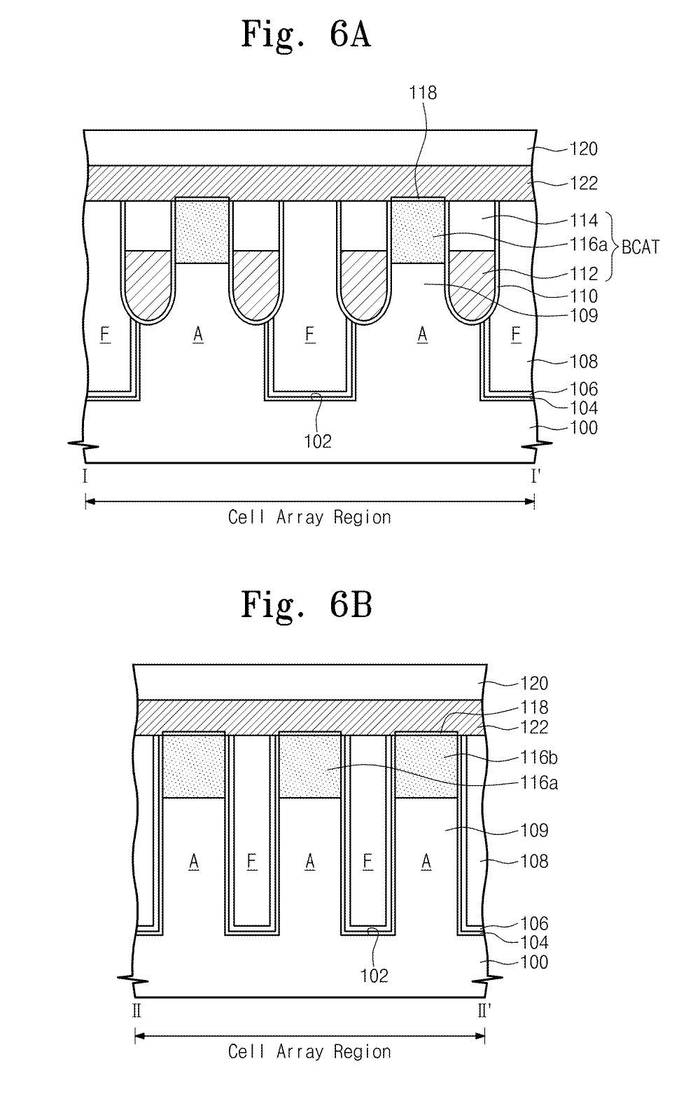

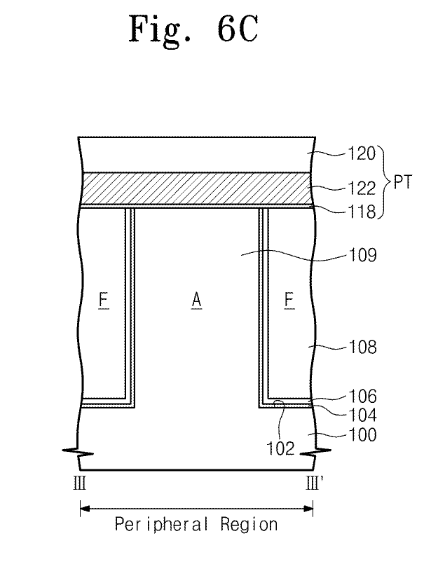

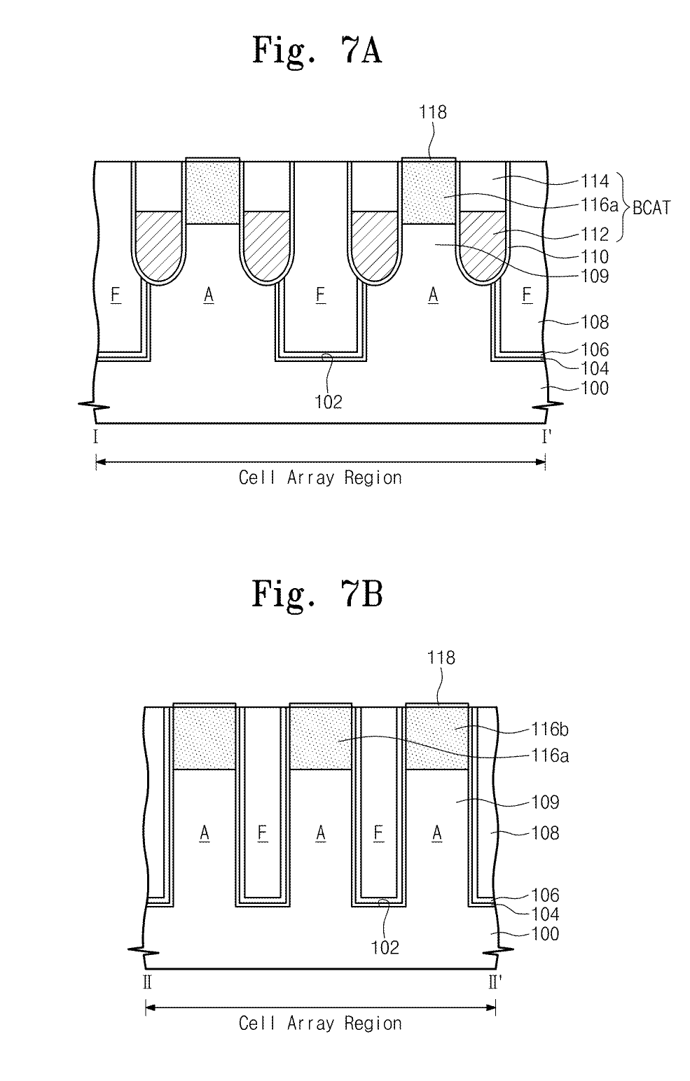

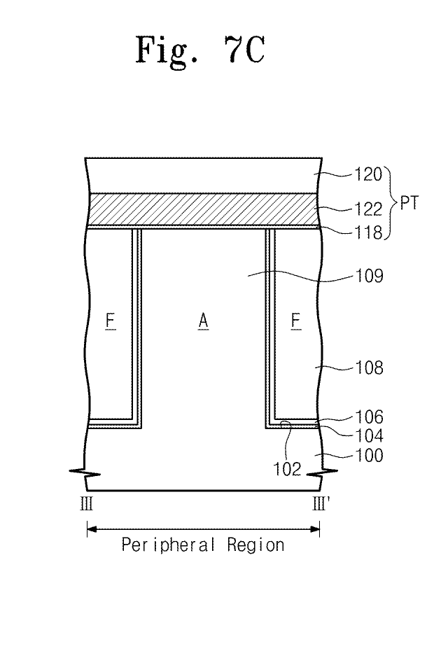

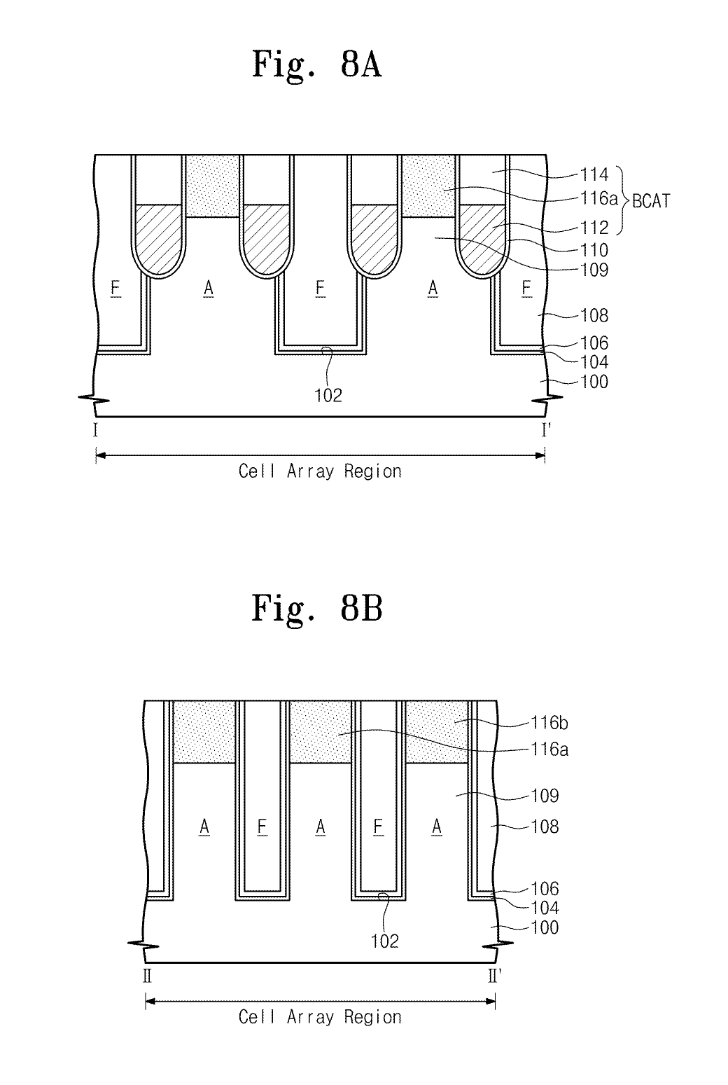

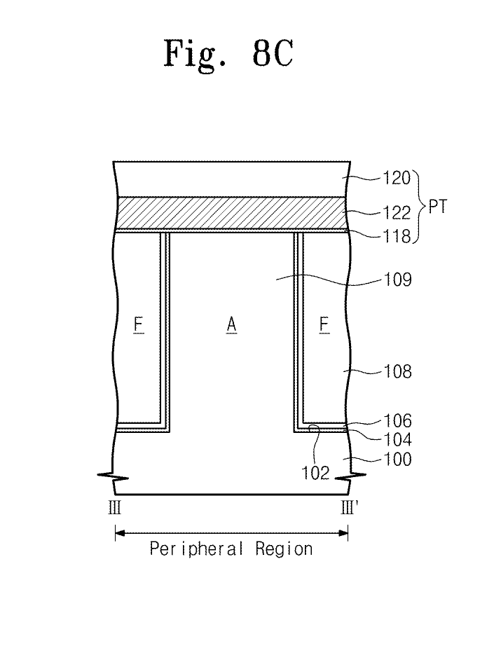

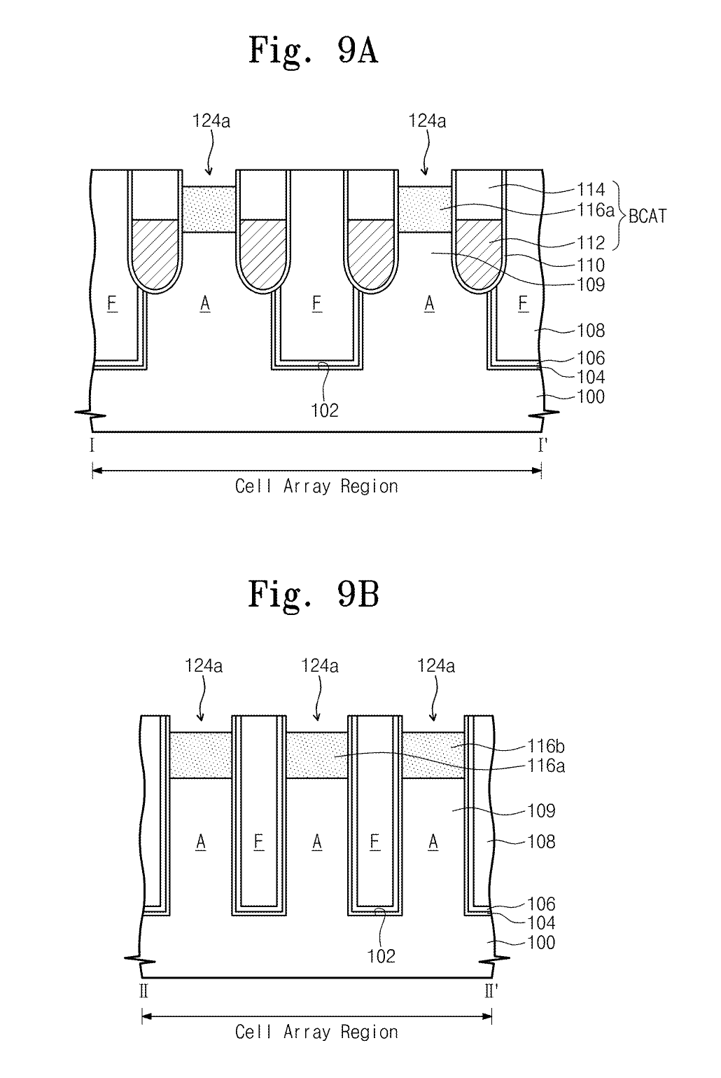

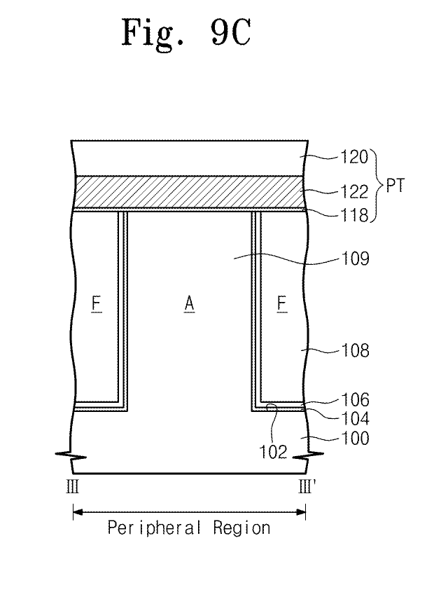

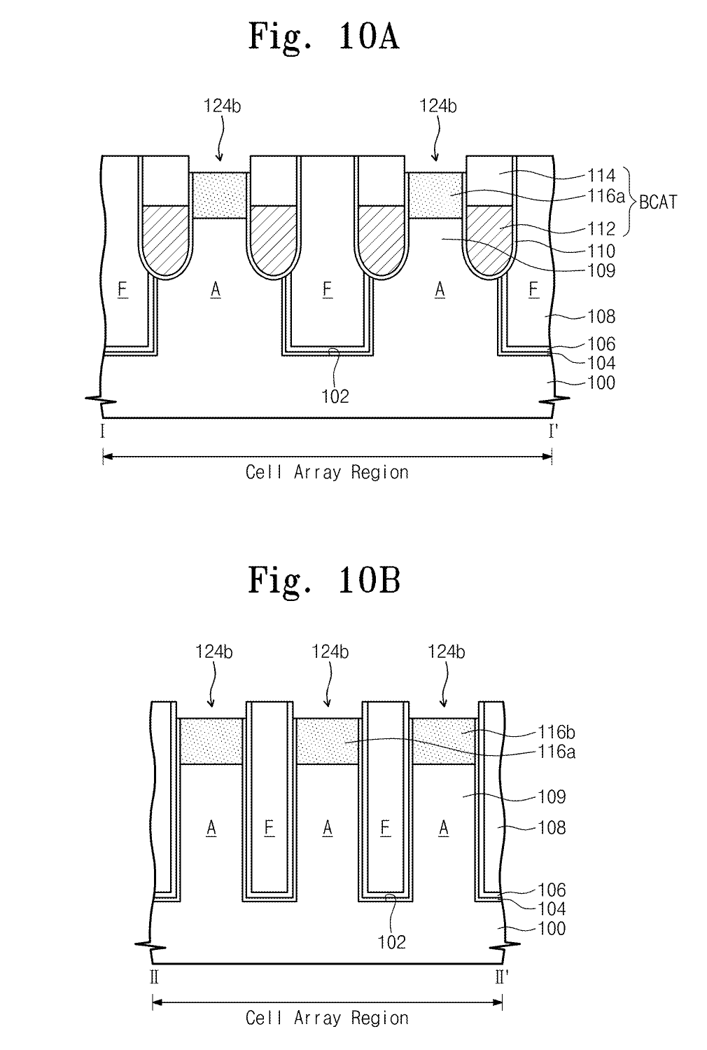

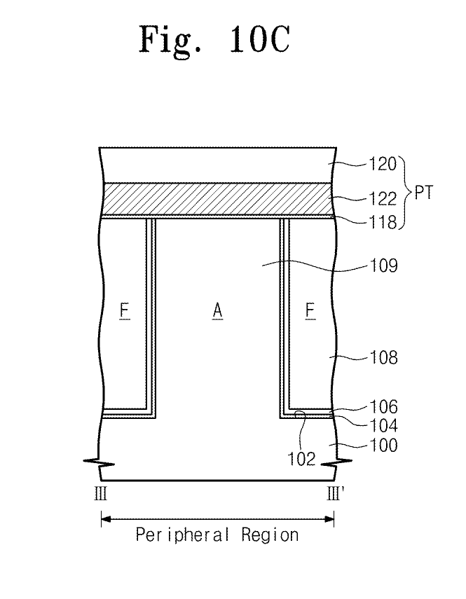

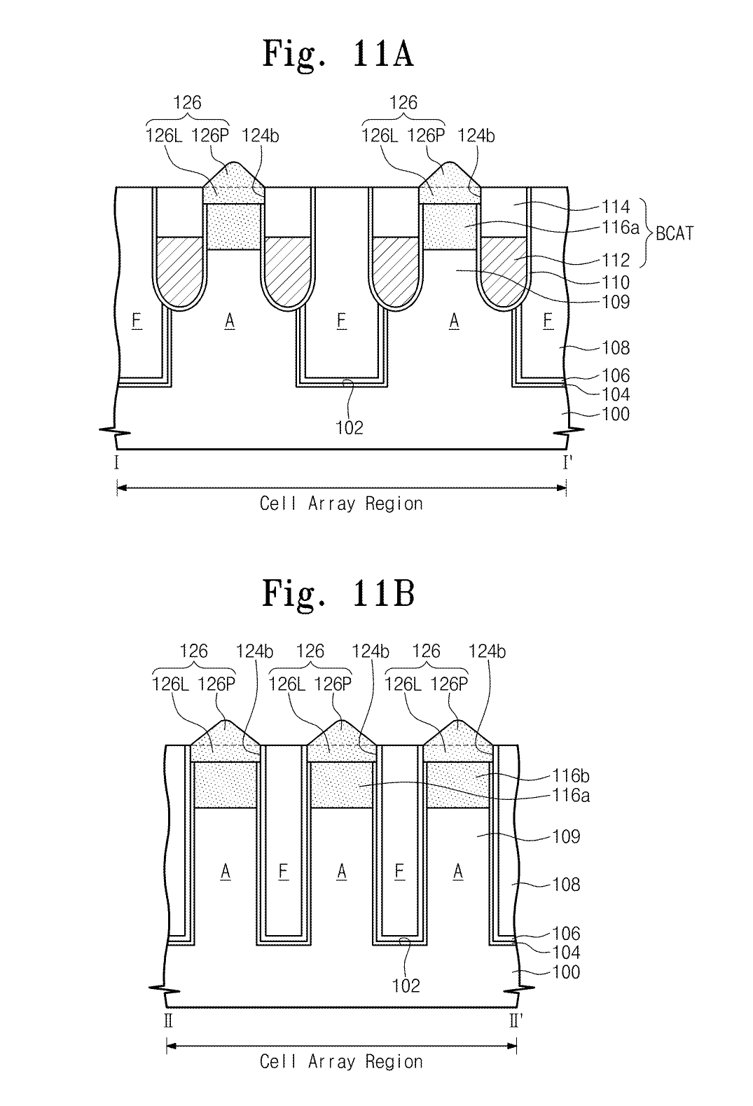

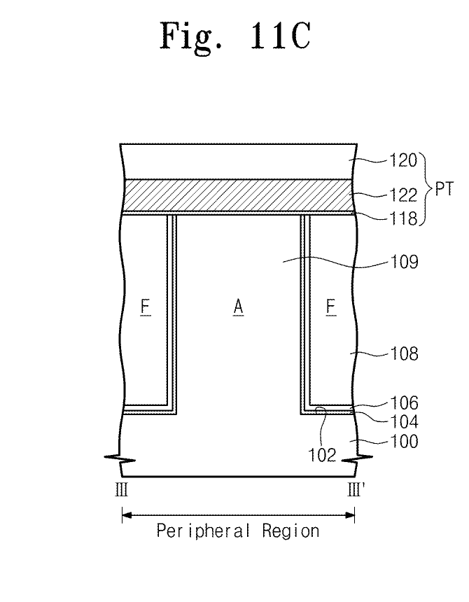

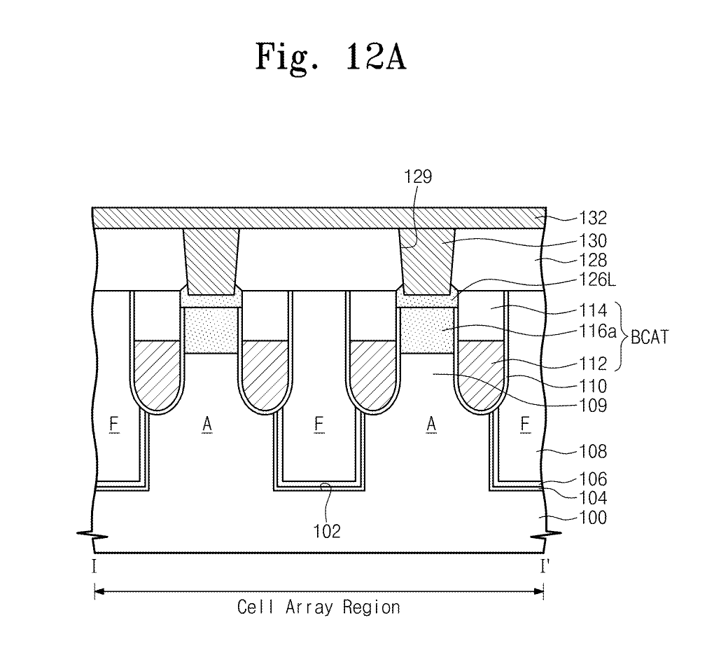

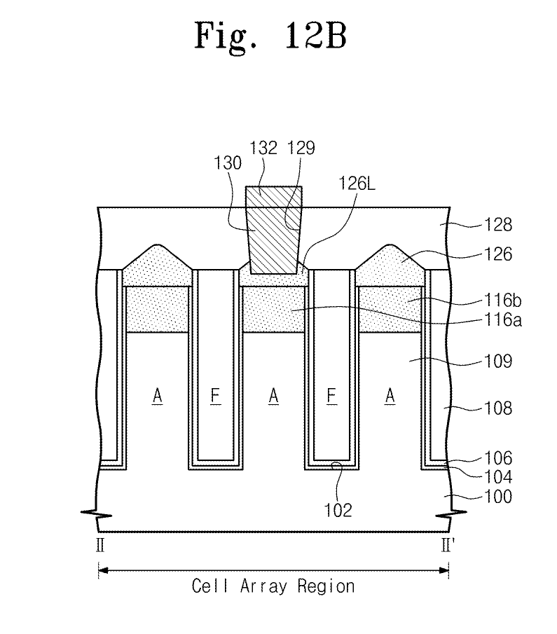

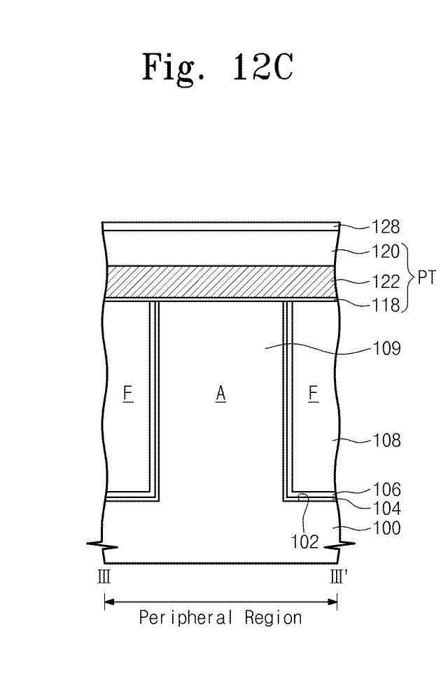

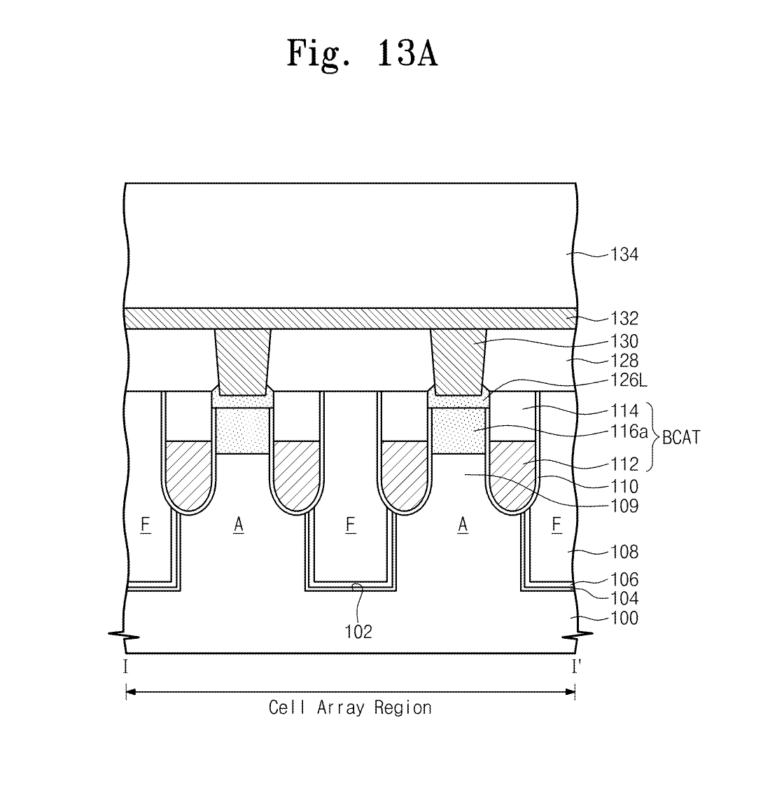

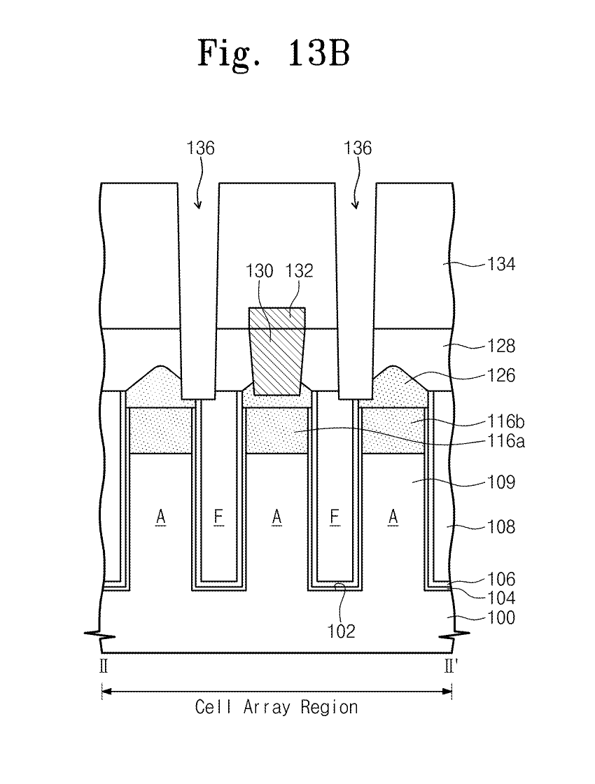

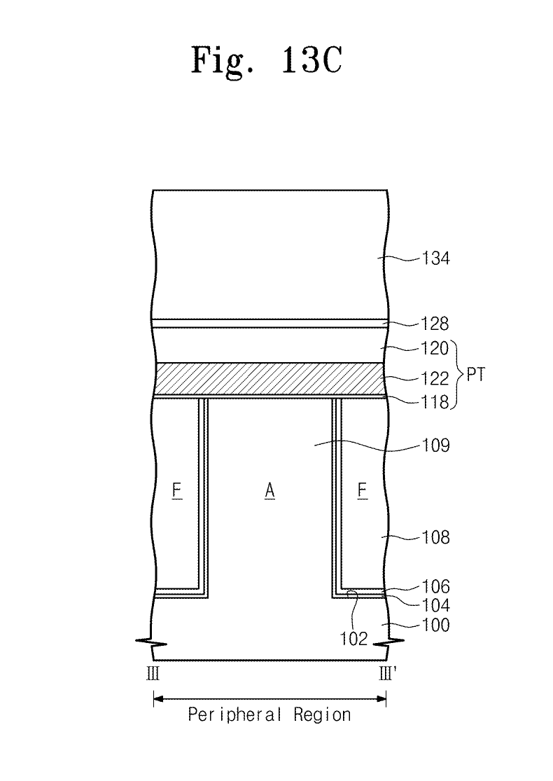

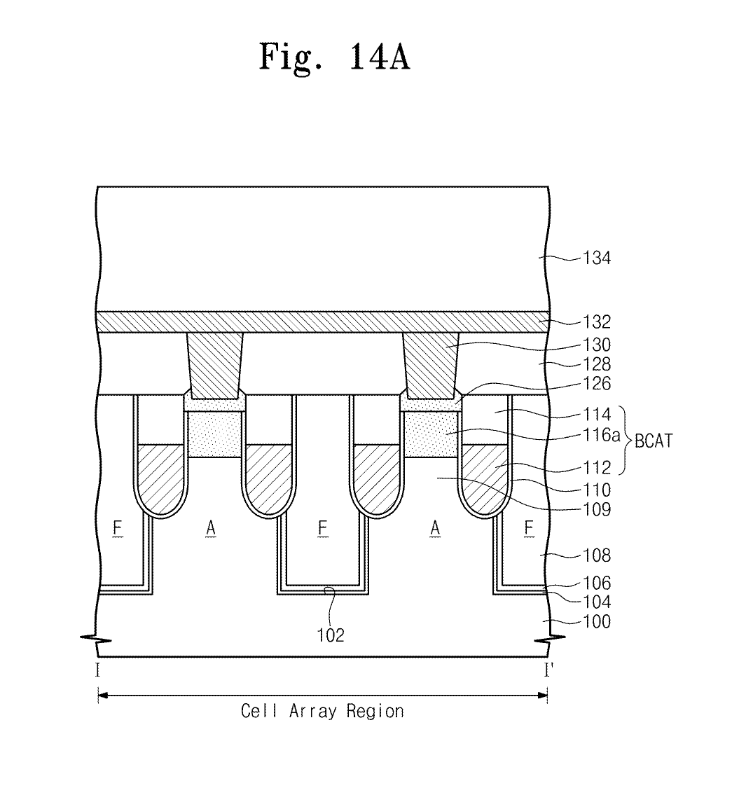

Referring to FIGS. 1A, 1B, and 3A through 3C, a first material layer 104 and a second material layer 106 are sequentially formed on the inner walls of the substrate 100 that delimit the trenches 102. More specifically, the first material layer 104 is formed conformally on the substrate 100 and to such a thickness that it does not fill the trenches 102. As used herein, the term “conformally” refers to a characteristic of the process to form a layer that replicates the topography of the underlying structure. Specifically, a conformal layer has substantially the same shape as the surface it covers and may have substantially the same thickness throughout.

In this example, the substrate 100 is formed of silicon, and the first material layer 104 is formed by a thermal oxidation process. Thus, in this case, the aforementioned damage of the substrate 100 created by the anisotropic etching process is cured by forming the first material layer 104.

The second material layer 106 is conformally formed on the first material layer 104. In this case, as well, the second material layer 106 is formed to such a thickness that the trenches 102 are not yet filled.

The second material layer 106 has an etch selectivity with respect to the first material layer 104. For example, the first material layer 104 may be formed of an oxide, and the second material layer 106 may be formed of a nitride. Also, the second material layer 106 may be formed by a chemical vapor deposition (CVD) process. The second material layer 106 may is used to suppress the diffusion or migration of a charge carrier (hole or electron).

Referring to FIGS. 1A, 1B, and 4A through 4C, the trenches 102 are then filled with insulating material to form gap-fill pattern 108. For example, an insulating layer is formed to such a thickness on the substrate 100 as to over-fill the trenches 102 and then the insulating layer is etched to expose the top surface of the substrate 100. The first and second material layers 104 and 106 may also be etched in conjunction with the insulating layer during the forming of the gap-fill pattern 108. The gap-fill pattern 108 and the first and second material layers 104 and 106 constitute a field isolation structure F delimiting the first active regions 109. (Note, reference character A denotes an active structure which will be referred to later on). Each of the first active regions 109 may be elliptical, as shown in FIGS. 1A and 1B.

Referring to FIGS. 1A, 1B, and 5A through 5C, a buried channel array transistor (B CAT) is formed in the cell array region. In an example of this process, first, recesses R are formed in the substrate 100. The recesses R extend along a second direction which subtends an angle with (i.e., is not parallel to) the direction of the major axes of the first active regions 109. Next, a first gate insulating layer 110 is formed conformally on the substrate 100 so as to cover surfaces defining the recesses R. Next, a first gate electrode 112 is formed to fill a lower portion of each recess R. As a result, the first gate electrode 112 extends along the second direction. Next, a second mask is formed on the first gate electrodes 112 to fill an upper portion of each recess R. Subsequently, impurities are implanted into the first active regions 109 adjacent the first gate electrodes 112 to form first and second doped regions 116a and 116b. The first and second doped regions 116a and 116b serve as a first source region and a first drain region of the BCAT. In sum, the BCAT includes first gate insulating layer 110, first gate electrode 112, and first and second doped regions 116a and 116b.

Note, during the steps described above with reference to FIGS. 5A through 5C, the peripheral region of the substrate 100 may be masked or covered.

Referring to FIGS. 1A, 1B, and 6A through 6C, a planar transistor PT is formed on the peripheral region of the substrate 100.

More specifically, a second gate insulating layer 118, a second gate conductive layer 122, and a third mask 120 are sequentially formed on the cell array region and the peripheral region of the substrate 100.

That part of the third mask 120 disposed on the peripheral region is patterned to expose the second gate conductive layer 122 thereunder, while the remainder of the third mask 120 is left over the second gate conductive layer 122 in the cell array region. The second gate conductive layer 122 is then etched using the third mask 120 as an etch mask, thereby forming a second gate electrode in the peripheral region. Subsequently, an ion implantation process is performed using the third mask 120 and/or the second gate electrode as an ion mask to form second source/drain regions (not shown) in the peripheral region. The second source/drain regions are formed in the first active region 109 at both sides of the second gate electrode and may have a different conductivity type than the substrate 100.

The planar transistor PT thus includes the second gate insulating layer 118, the second gate electrode, source/drain regions (not shown), and the third mask 120 in the peripheral region.

Referring to FIGS. 1A, 1B, and 7A through 7C, the third mask 120 and the second gate conductive layer 122 are selectively removed from the cell array region.

In this respect, the peripheral region may be covered with a mask (not shown) while the third mask 120 and the second gate conductive layer 122 are removed from the cell array region. Then, the mask is removed from the peripheral region, at which time the third mask 120 and the second gate conductive layer 122 remain locally in the peripheral region as shown in FIG. 7C.

Referring to FIGS. 1A, 1B, and 8A through 8C, the second gate insulating layer 118 is removed from the cell array region to expose the first active regions 109.

In this example, the second gate insulating layer 118 is removed by a wet etch technique. For instance, the second gate insulating layer 118 may be removed using a wet etchant including dilute hydrofluoric acid.

Referring to FIGS. 1A, 1B, and 9A through 9C, upper portions of the first active regions 109 exposed in the cell array region are etched to form first hollows 124a. The hollows 124a may be formed using an anisotropic etching technique. For instance, the upper portions of the first active regions 109 may be plasma etched. At this time, the first and second doped regions 116a and 116b are not removed completely. That is, the hollows 124a expose remnants of the first and second doped regions 116a and 116b at the bottom thereof.

As described above, each of the first material layer 104 and the first gate insulating layer 110 may be an oxide layer. In the illustrated example, the hollows 124a also expose the first material layer 104 and an upper portion of the first gate insulating layer 110 at sides thereof. Alternatively, i.e., in another example, the process of forming the first hollows 124a also entails etching only portions of the first active regions 109 which include the second doped regions 116b. In this case, only the second doped regions 116b are exposed at the bottom of the first hollows 124a, and an upper portion of the first material layer 104 is exposed at the sides of the first hollows 124a.

Referring to FIGS. 1A, 1B, and 10A through 10C, the first material layer 104 and/or the first gate insulating layer 110 exposed by the first hollows 124a are etched to form second hollows 124b. The second hollows 124b may be formed using a wet etching technique. For instance, in the case in which the first material layer 104 or the first gate insulating layer 110 is an oxide layer, the second hollows 124b may be formed using a wet etchant including dilute hydrofluoric acid. In addition, the second hollows 124b are preferably formed using a wet etchant having an etch selectivity with respect to the second material layer 106 or the second mask 114. That is, the wet etchant used for forming the second hollows 124b may be selected to realize a faster etch rate for the first material layer 104 than for the second material layer 106 or the second mask 114. To this end, the first material layer 104 and/or the first gate insulating layer 110 may be an oxide layer and the second material layer 106 and the second mask 114 may be a nitride layer.

In any case, the second hollows 124b are substantially wider than the first hollows 124a, respectively, because they are formed by etching the first material layer 104 exposed by the first hollows 124a. The second material layer 106 or the second mask 114, as well as the first active regions 109, are exposed by the second hollows 124b.

In addition, the resultant structure in which the first active regions 109 are exposed is subjected to a cleaning process (optional). For example, in the case in which a cleaning process is performed, a natural oxide layer or contaminants are removed using plasma.

Referring to FIGS. 1A, 1B, and 11A through 11C, second active regions 126 are formed on the first active regions 109 to such a thickness as to fill the second hollows 124b, respectively. The first active regions 109 and the second active regions 126 will be referred to hereinafter as active “patterns”.

In an example of this process, the second active patterns 126 are formed by a selective epitaxial growth (SEG) process using the surfaces of the first active patterns 109 exposed by the second hollow 124b as a seed layer. As a more specific example in which the second active patterns 126 are formed of silicon, the SEG process is performed using hydrogen as a carrier gas and dichlorosilane (SiCl₂H₂) and hydrogen chloride (HCl) as reaction gas.

Furthermore, the first and second doped regions 116a and 116b are in effect extended upwardly by doping the second active patterns 126 with impurities during the SEG process. To this end, the second active patterns 126 may be doped with impurities having the substantially same conductivity type as the first and second doped regions 116a and 116b.

As a result, each of the second active regions 126 includes a lower portion 126L and an upper portion 126P. The lower portion 126L of the second active pattern fills the second hollow 126b. The upper portion 126P is pyramidal, i.e., has a substantially upwardly tapered shape and more specifically, has a cross section in the shape of a truncated cone whose apex is rounded. Because the second active pattern 126 protrudes laterally over the field isolation structure F and because of its upwardly tapered shape, electrical shorts between adjacent second active patterns 126 are very unlikely to occur.

The sequentially stacked first and second active patterns 109 and 126 constitute active structures A. More specifically, each of the active structures A has portions disposed on opposite sides of the first gate electrode 112, respectively, and one of the portions comprises a first doped region 116a and the other of the portions comprises a second doped region 116b. First and second doped regions 116a and 116b constitute the upper portion of each first active pattern 109 extending from the bottom of a second active pattern 126 to the top of the undoped portion (in this example) of the first active pattern 109.

Referring to FIGS. 1A, 1B, and 12A through 12C, a first interlayer dielectric, first contact plugs 130 and bit lines 132 are formed on the resultant structure.

More specifically, the first interlayer dielectric 128 is formed on the resultant structure and is patterned (etched) to form first contact holes 129 that expose the first doped regions 116a, respectively. In this process, the first interlayer dielectric 128 may be over-etched such that the upper portion 126P of each second active pattern 126 is etched until the lower portion 126L of the second active pattern 126 is exposed.

Then the first contact holes 129 are filled with conductive material to form the first contact plugs 130. Next, the bit lines 132 are formed on the first interlayer dielectric 128 as electrically connected to the first contact plugs 130. As a result, in this example, each of the first plugs 130 has a bottom surface contacting the second lower portion 126L of the active pattern 126 and a top surface contacting the bit line 132.

In addition, each of the bit lines 132 may be formed to extend along a third direction (see FIG. 1A) crossing the second direction, namely, the direction in which the first gate electrodes 112 extend. The third direction may be perpendicular to the second direction.

As is clear from the description above, the respective lower portions 126L of the second active patterns 126 are substantially wider than the first active patterns 109. Thus, the electrical resistance between the first doped region 116a and the first contact plug 130 is, in effect, reduced by the active pattern 126. In addition, this enhances the reliability of the electrical connection between the BCAT and the bit line 132.

Referring to FIGS. 1A, 1B, and 13A through 13C, a second interlayer dielectric 134 is formed on the bit lines 132 and subsequently, second contact holes 126 are formed to expose at least portions of the second doped regions 116b, respectively.

More specifically, in this example, the second interlayer dielectric 134 is formed to such a thickness as to fill the gaps between the bit lines 132, and a fourth mask (not shown) having openings juxtaposed with at least portions of the second doped regions 116b is formed on the second interlayer dielectric 134. Then, the second interlayer dielectric 134 and the first interlayer dielectric 128 are sequentially etched using the fourth mask as an etch mask. Also, upper portions of the second doped regions 116b may also be etched using the fourth mask, and the patterned first and second interlayer dielectrics 128 and 134 as an etch mask. In this case, the lower portions 126L of the second active patterns are exposed.

In particular, according to an aspect of the inventive concept, each second contact hole 126 exposes part of a second active pattern 126 which lies over a second doped region 116b as well as part of the field isolation structure F. Moreover, the etching process at this stage can be carried out until the second contact hole 126 exposes the lower portion 126L of the second active pattern (and the field isolation region F).

Referring to FIGS. 1A, 1B, and 14A through 14C, the second contact holes 126 are filled with conductive material to form second contact plugs 138.

As a result, the bottom surface of the second contact plug 138 contacts the exposed top surface of the second active pattern 126. As is clear from the description above, the respective lower portions 126L of the second active patterns are substantially wider than the upper portions 126P thereof, respectively. Therefore, electrical resistance between the second doped region 116b and the second contact plug 138 is in effect decreased by the second active pattern 126. In some cases, though, the second contact hole 126 can be formed to such a depth as to expose the second doped region 116b.

Referring to FIGS. 1A, 1B, and 15A through 15C, capacitor CAP may be formed on the second interlayer dielectric 134. In this case, the capacitor CAP is electrically connected to the second contact plug(s) 138.

The CAP is formed, for example, by forming a first sacrificial layer (not shown) on the second interlayer dielectric 134, forming a hole in the sacrificial layer that exposes the second contact plug 138, and then conformally forming a lower electrode layer on the first sacrificial layer to such a thickness that the lower electrode layer does not fill the hole completely. Then, a second sacrificial layer (not shown) is formed to fill what remains of the hole, and the second sacrificial layer and the lower electrode layer are etched to expose a top surface of the first sacrificial layer. As a result, a lower electrode 140 having the shape of a cup or a cylinder whose bottom is closed is formed in the hole. Subsequently, the first and second sacrificial layers are removed, and a capacitor dielectric 142 is conformally formed on the exposed surface of the lower electrode 140 to such a thickness that the capacitor dielectric 142 does not fill the lower electrode 140. Then, an upper electrode 144 is formed on the capacitor dielectric 142. Note, however, a capacitor whose lower electrode has a shape other than those described above can be formed.

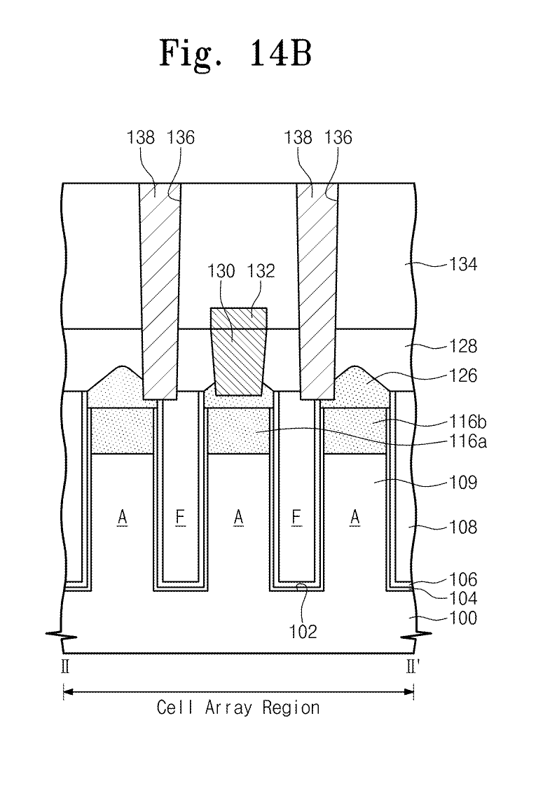

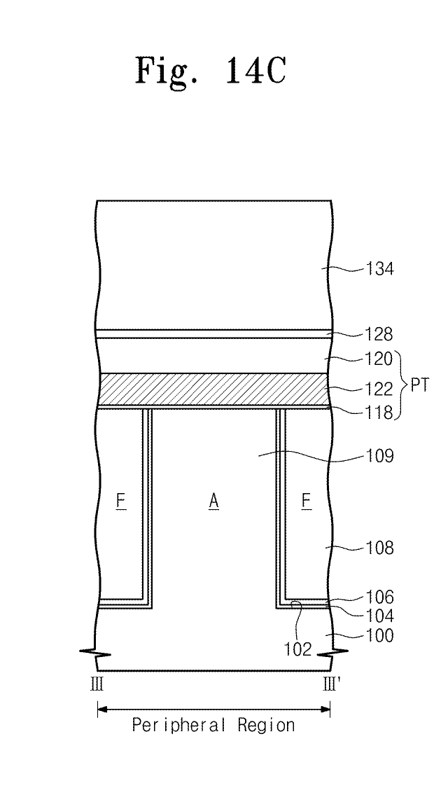

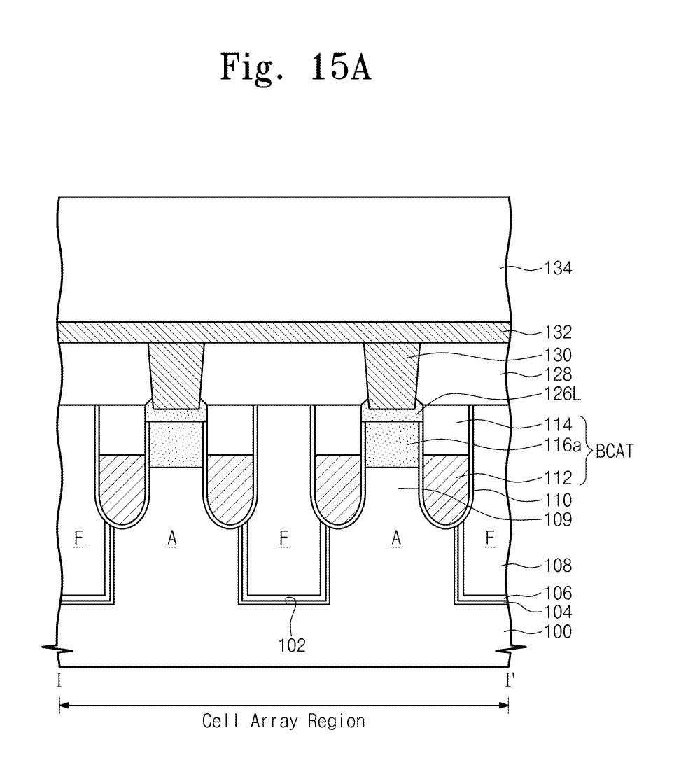

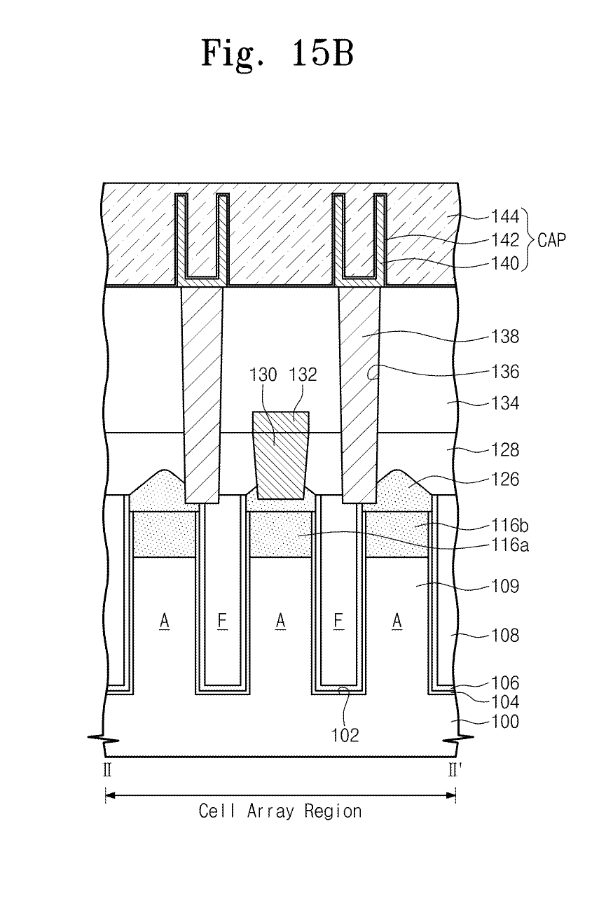

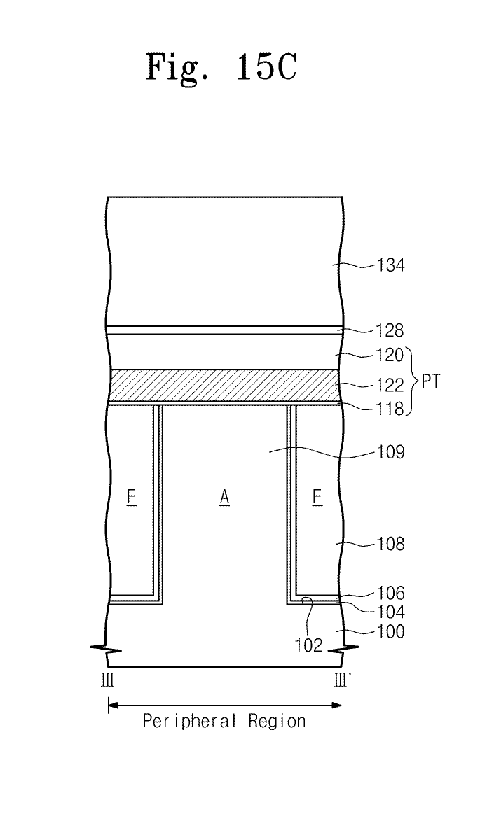

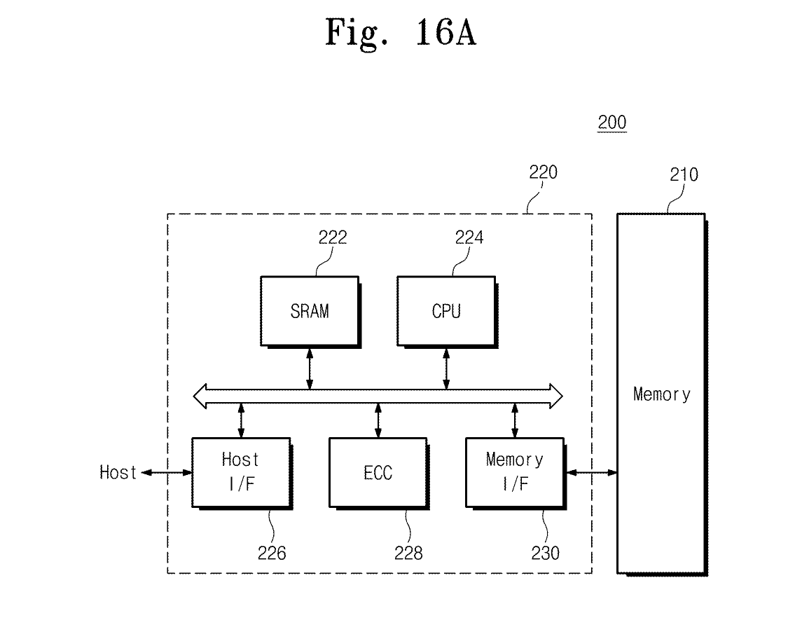

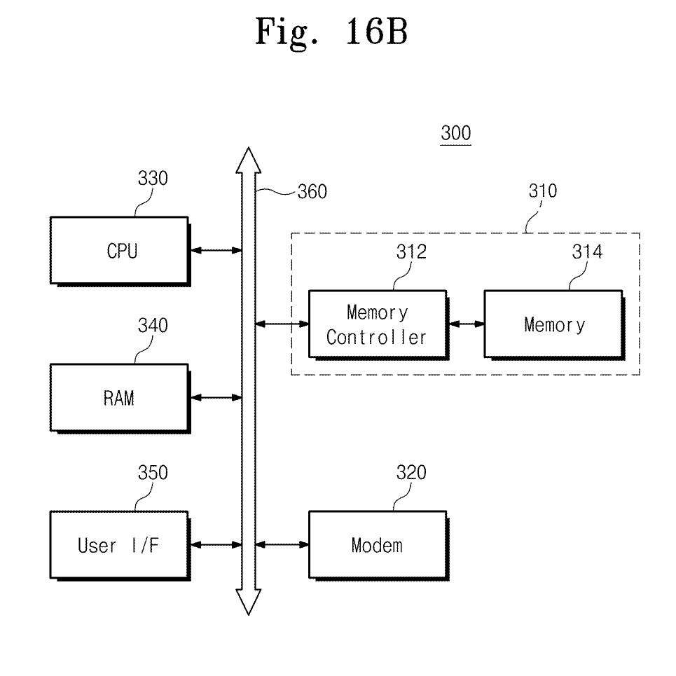

FIG. 16A illustrates a memory card including a memory device according to the inventive concept.

Referring to FIG. 16A, an example of a memory card 200 which can employ a semiconductor device according to the inventive concept includes a semiconductor memory 210, and a memory controller 220 configured to control the exchanging of data between a host and the semiconductor memory 210.

The semiconductor memory 210 comprises a semiconductor device (fabricated) according to the inventive concept.

The memory controller 220 has a central processing unit (CPU) 224, a static random access memory (SRAM) 222 serving as an operation memory of a central processing unit (CPU) 224, a host interface 226, an error correction code (ECC) 228, and a memory interface (I/F) 230. The host interface 226 contains at least one protocol for data exchange between the host and the memory card 200. The error correction code (ECC) 228 is for detecting and correcting at errors that may be contained in data read from the semiconductor memory 210. The central processing unit (CPU) 224 controls the exchanging of data between the memory controller 220 and, for example, the semiconductor memory 210. To facilitate such a data exchange, the memory interface 230 provides an interface between the memory controller 220 and the semiconductor memory 210

FIG. 16B illustrates an information processing system, such as a mobile device or a computer, including a memory device according to the inventive concept.

In the example shown in FIG. 16B, the information processing system 300 includes a memory system 310, a modem 320, a central processing unit (CPU) 330, a random access memory (RAM) 340, and a user interface 350 that are electrically connected to a system bus 360. The memory system 310 stores data processed by the central processing unit (CPU) 330 and data inputted from the outside (via the user interface 350 and/or the modem 320). The memory system 310 includes a memory 312 and a memory controller 314. The memory system 310 may be a memory card of the type described with reference to FIG. 16A. The information processing system 300 itself may be embodied as a memory card, or as a solid state drive (SSD), a camera image sensor or an application chip set. In the case in which the information processing system 300 comprises a solid state drive (SSD), the information processing system 300 can stably and reliably store data in the memory system 310.

As described above, according to an aspect of the inventive concept, the second active patterns 126 are formed so as to be wider than the first active patterns 109, such that the subsequently formed contact plugs have a relatively large contact area over which they are electrically connected to the active regions, specifically, the doped regions. Accordingly, the structure can be characterized as exhibiting relatively low contact resistance. Furthermore, short circuits do not occur between adjacent ones of the second active patterns 126 because the second active patterns 126 protrude laterally over the field isolation structure F and taper upwardly, i.e., extend in directions away from each other in the upward direction.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

1. A semiconductor device, comprising:
a field isolation structure disposed in a substrate, the field isolation structure including a gap-fill pattern, a first material layer surrounding the gap-fill pattern, and a second material layer interposed between the first material layer and the gap-fillpattern, the first material layer surrounding at least a portion of the second material layer; and
an active structure surrounded by the field isolation structure, and including a first active pattern having a top surface located beneath the level of the top surface of the field isolation structure, and a second active pattern protruding upwardly from the first active pattern to such an extent that the top thereof is located above the level of the top surface of the field isolation structure, and wherein the first active pattern comprises a buried channel region of a transistor, and the second active pattern contacts the second material layer.

2. The device of claim 1, wherein a lowermost portion of the second active pattern is wider than an uppermost portion of the first active pattern.

3. The device of claim 1, wherein the second active pattern has a lower portion spanning sections of the second material layer and having substantially vertical sidewall surfaces, and an upper portion that tapers upwardly in a direction away from the lower portion.

4. The device of claim 1, wherein sides of the second active pattern are delimited by the field isolation structure.

5. The device of claim 1, wherein the second material layer is of material having an etch selectivity with respect to the first material layer.

6. The device of claim 1, further comprising an elongated gate electrode of the transistor disposed in the substrate, and a gate insulating layer interposed between the substrate and the gate electrode, and
wherein the top surface of the gate electrode is located beneath the level of the top surface of the first active pattern, and the first active pattern includes first and second doped regions of the substrate located adjacent and on opposite sides, respectively, of the gate electrode.

7. The device of claim 6, wherein each of the first and second doped regions is located at the top of the first active pattern adjacent the second active pattern and is narrower than a lower portion of the first active pattern.

8. The device of claim 7, further comprising:
a bit line elongated along a direction different from that along which the gate electrode is elongated; and
a first contact plug electrically connecting the bit line to the first doped region, and
wherein the first contact plug contacts a lower portion of the second active pattern that is disposed on the first doped region.

9. The device of claim 7, further comprising:
a capacitor disposed on the substrate; and
a second contact plug electrically connecting the capacitor to the second doped region, and
wherein the second contact plug contacts a lower portion of the second active pattern disposed on the second doped region.

10. The device of claim 9, wherein the second contact plug also contacts at least a portion the field isolation structure.

11-20. (canceled)
